(19) United States
(12) Patent Application Publication
(10) Pub. No.: US 2011/0096474 A1
(43) Pub. Date: Apr. 28, 2011

(54) ELECTRONIC DEVICE

(75) Inventor: ZHAN-YANG LI, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/697,221

(22) Filed: Jan. 30, 2010

(30) Foreign Application Priority Data
Oct. 26, 2009 (CN) 200920313288.2

(51) Int. Cl. H05K 5/00; F16M 13/00

(52) U.S. Cl. 361/679.01; 248/636

(57) ABSTRACT

An electronic device includes a chassis, a mounting apparatus, at least one first vibration absorbing member, and at least one second vibration absorbing member. The chassis has a bottom wall. The mounting apparatus is adapted to accommodate an apparatus that vibrates. The mounting apparatus includes a bracket, a side plate, a fastener securing the side plate to the bracket. At least one first vibration absorbing member is secured to the mounting apparatus and arranged to isolate the bottom wall of the chassis. At least one U-shaped second vibration absorbing member isolates the side plate from the fastener and defines a receiving room.

### BACKGROUND

1. Technical Field

The present disclosure relates to electronic devices, and particularly to a mounting apparatus in an electronic device.

2. Description of Related Art

Usually, fans are secured in an electronic device. The fans are conventionally secured to the electronic device by a plurality of screws. However, the fans will vibrate and produce noise when running, so it is important to stably secure the fans in the electronic device.

### BRIEF DESCRIPTION OF THE DRAWINGS

FIG. 1 is an isometric, exploded view of an embodiment of a mounting apparatus.

FIG. 2 is similar to FIG. 1, but viewed from another aspect.

FIG. 3 is an isometric view of an elastic clamp of FIG. 1.

FIG. 4 is an isometric view of an elastic gasket of FIG. 1.

FIG. 5 is an enlarged sectional view taken along line V-V of FIG. 4.

FIG. 6 is an assembled view of the mounting apparatus.

FIG. 7 is similar to FIG. 6, but viewed from another aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

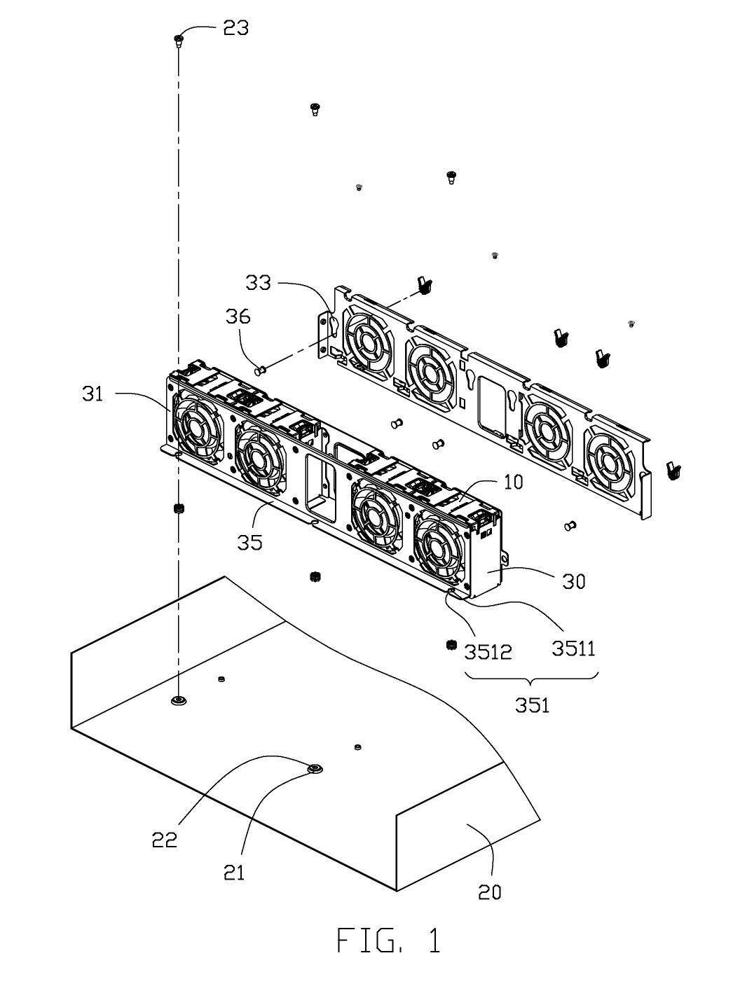

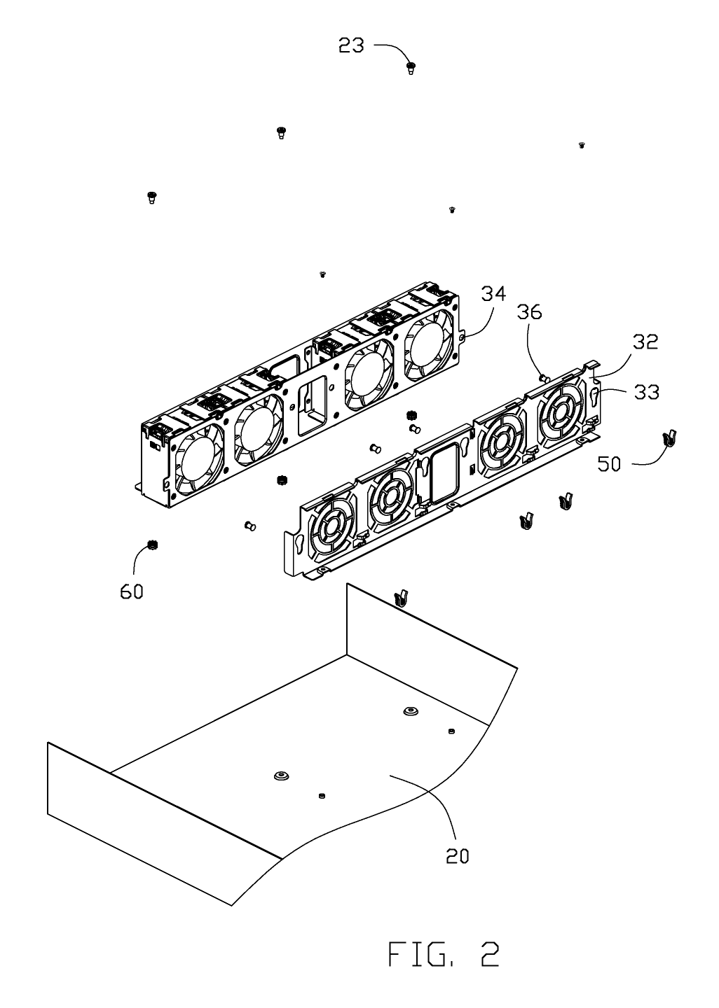

Referring to FIG. 1 and FIG. 2, a mounting apparatus 30 for fans 10 is fixed in an electronic device 20. A plurality of protrusions 21 projects from the electronic device 20. A hole 22 is defined in each protrusion 21 to receive a screw 23.

The mounting apparatus 30 has two side plates 31, 32. A flange 35 extends from the side plate 31. A plurality of mounting holes 351 is defined in the flange 35. Each mounting hole 351 has a guiding portion 3511 and a receiving portion 3512 connected to the guiding portion 3511. A plurality of calabash-shaped holes 33 is defined in the side plate 32. Each hole 33 includes a narrow portion capable of receiving and in which a rivet 36 can engage, and a wide portion capable of releasing the rivet 36. A plurality of circular holes 34 is defined in the mounting apparatus 30 corresponding to the hole 33 to secure the side plate 32.

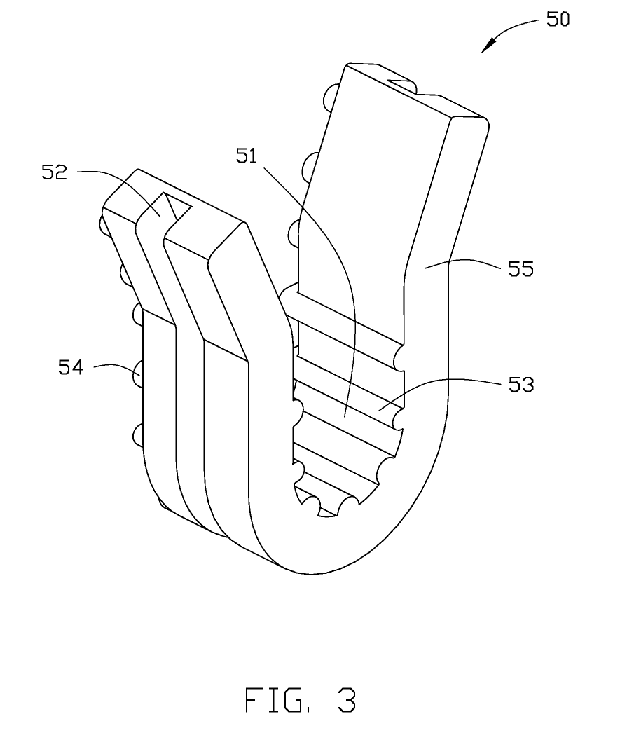

Referring to FIG. 3, the mounting apparatus 30 includes an elastic clamp 50 and an elastic gasket 60. The elastic clamp 50 is U-shaped. A receiving room 51 is defined in the elastic clamp 50 to receive a corresponding rivet 36. A recess 52 is defined in the elastic clamp 50 to receive an edge bounding the hole 33. A plurality of first projections 53 projects from the inner side of the elastic clamp 50 to separate the side plate 32 and the rivet 36. An extension direction of the first projection 53 is the same as an extension direction of the rivet 36. The first projection 53 has a semi-circular section. A plurality of second projections 54 projects from the side of the elastic clamp 50. The elastic clamp 50 has two free ends 55 extending outward to form a generally V-shaped opening.

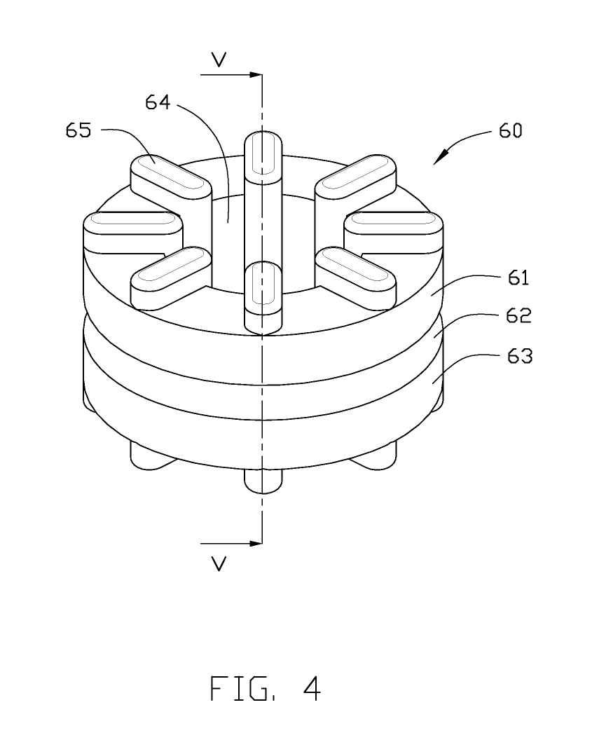

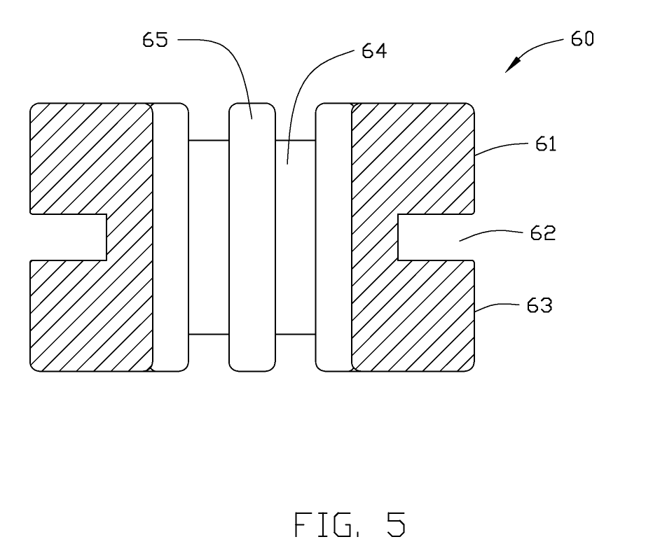

Referring to FIGS. 4 and 5, the elastic gasket 60 includes a first resilient portion 61, a neck portion 62, a second resilient portion 63, and a through hole 64. A plurality of third projections 65 projects from the first and second resilient portions 61, 63 to prevent vibration from the fans 10 transmitting through the mounting apparatus 30 to the electronic device 20.

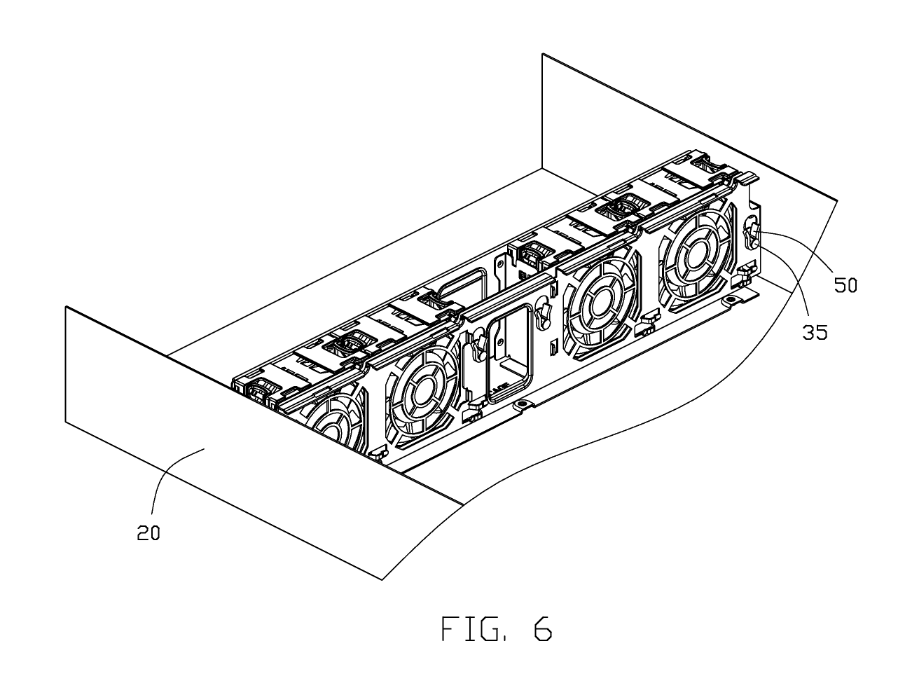

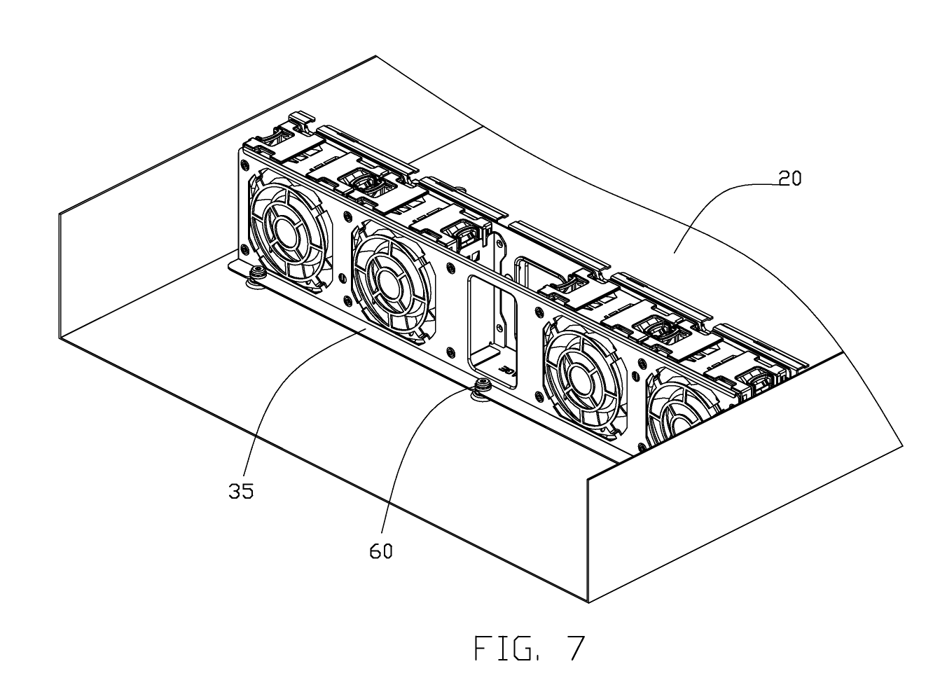

Referring to FIGS. 6 and 7, the rivets 36 are inserted in the hole 33s and the circular hole 34. The elastic clamps 50 are mounted on the rivets 36. The receiving rooms 51 receive the corresponding rivets 36. The clamps 50 hold the rivets 36 away from the edges of the holes 33 to prevent transmission of vibration.

The neck portion 62 is inserted in the receiving portion 3512 through the guiding portion 3511. The flange 35 is sandwiched between the first and second resilient portions 61, 63. The screw 23 is inserted in the through hole 64 and the hole 22 to fix the mounting apparatus 30 in the electronic device 20. The first resilient portion 61 isolates the screw 23 from the flange 35. The second resilient portion 63 isolates the protrusion 21 from the flange 35. The third projection 65 also resists against the mounting apparatus 30 to prevent transmission of vibration to the electronic device 20 to decrease noise.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. An electronic device, comprising:
a chassis having a bottom wall;
a mounting apparatus adapted to accommodate an apparatus that vibrates, the mounting apparatus comprising:
a bracket;
a side plate;
a fastener securing the side plate to the bracket;
at least one first vibration absorbing member secured to the mounting apparatus and arranged to isolate the bottom wall of the chassis;
at least one U-shaped second vibration absorbing member capable of isolating the side plate from the fastener, wherein the at least one second vibration absorbing member defines a receiving room.

2. The electronic device of claim 1, wherein a recess is defined on the exterior of the at least one second vibration absorbing member, and the recess engages an edge of the side plate.

3. The electronic device of claim 2, wherein a calabash-shaped hole is defined in the side plate, and the recess engages the edge of the calabash-shaped hole.

4. The electronic device of claim 3, wherein the calabash-shaped hole comprises a narrow portion and a wide portion, the fastener is fixed in the narrow portion.

5. The electronic device of claim 1, wherein a plurality of first projections protrudes from an inner surface of the at least one second vibration absorbing member to absorb vibration.

6. The electronic device of claim 1, wherein a plurality of second projections protrudes from a side of the at least one second vibration absorbing member and abut the side plate.

7. The electronic device of claim 1, wherein the fastener comprises two free ends extending outward to form a V-shaped opening.

8. The electronic device of claim 1, wherein the fastener is a rivet.

9. A bracket assembly, comprising:
a bracket;
a side plate;
a fastener securing the side plate to the bracket;
a U-shaped vibration absorbing member capable of isolating the side plate from the fastener, wherein the vibration absorbing member defines a receiving room.

10. The bracket assembly of claim 9, wherein a recess is defined on the exterior of the vibration absorbing member, and the recess engages an edge of the side plate.

11. The bracket assembly of claim 10, wherein a calabash-shaped hole is defined in the side plate, and the recess engages the edge of the calabash-shaped hole.

12. The bracket assembly of claim 11, wherein the calabash-shaped hole comprises a narrow portion, fixing the fastener, and a wide portion.

13. The bracket assembly of claim 9, wherein a plurality of first projections protrudes from an inner surface of the vibration absorbing member to absorb vibration.

14. The bracket assembly of claim 9, wherein a plurality of second projections protrudes from a side of the vibration absorbing member and abut the side plate.

15. The bracket assembly of claim 9, wherein the fastener comprises two free ends extending outward to form a V-shaped opening.

16. The bracket assembly of claim 9, wherein the fastener is a rivet.
